(19) United States
(12) Patent Application Publication
(10) Pub. No.: US 2010/0218807 A1
(43) Pub. Date: Sep. 2, 2010

(54) 1-DIMENSIONAL CONCENTRATED PHOTOVOLTAIC SYSTEMS

(75) Inventors: Mark A. Arbore, Los Altos, CA (US); David Klein, Palo Alto, CA (US); George E. Conway, San Mateo, CA (US)

Correspondence Address: K&L Gates LLP;IP Docketing, 630 HANSEN WAY, PALO ALTO, CA, 94304, US

(73) Assignee: SKYWATCH ENERGY, INC., Mountain View, CA (US)

(21) Appl. No.: 12/712,122

(22) Filed: Feb. 24, 2010

Related U.S. Application Data
(60) Provisional application No. 61/156,428, filed on Feb. 27, 2009.
(60) Provisional application No. 61/181,612, filed on May 27, 2009.

(51) Int. Cl. H01L 31/052

(52) U.S. Cl. 136/246

(57) ABSTRACT

Systems, methods, and apparatus by which solar energy may be collected to provide electricity are disclosed herein.

### CROSS REFERENCE TO RELATED APPLICATIONS

This applications claims benefit of priority to U.S. Provisional Patent Application Ser. No. 61/156,428, titled “Designs For 1-Dimensional Concentrated Photovoltaic Systems,” filed Feb. 27, 2009 and to U.S. Provisional Patent Application Ser. No. 61/181,612, also titled “Designs For 1-Dimensional Concentrated Photovoltaic Systems,” filed May 27, 2009, each of which is incorporated by reference herein in its entirety.

### FIELD OF THE INVENTION

The invention relates to the collection of solar energy to provide, for example, electric power.

### BACKGROUND

Alternate sources of energy are needed to satisfy ever increasing world-wide energy demands. Solar energy resources are sufficient in many geographical regions to satisfy such demands, in part, by provision of electric power. Solar energy electric power generation is currently evolving from a niche technology into a mainstream industry. As it makes this transition, two key challenges are system cost and achievable scale (i.e. how much generating capacity could be installed, worldwide, without driving up the system cost by exhausting near-term supply of components/materials). System design and architecture may dramatically impact both of these factors by, for example, minimizing materials usage and by avoiding the use of exotic materials. Also of importance is a fundamental architectural choice: the degree of optical concentration onto the receiver. Most currently installed solar-energy systems operate either without (i.e., unity) concentration, or at high (>˜20×) concentration.

Non-concentrating designs, while simple, may consume extremely large quantities of silicon, and/or other panel materials, potentially outstripping worldwide supply in the event of a rapid ramp-up in solar panel installation rates. For concentrated systems, the historical focus on high-concentration is due to the high cost of multi junction cells (per unit area) or to the fact that solar-thermal energy generation typically utilizes very high operating temperatures to be efficient. Highly concentrating designs are inherently complex, due to the tight tolerances on fabrication, assembly, and two-dimensional tracking of solar motion. These extremes (unity- and high-concentration) may not reflect the optimal design for high-volume production of solar generation capacity, particularly for direct PV systems.

### SUMMARY

We disclose one-dimensional-concentrating photovoltaic (CPV) systems, apparatus, concentrating geometries, tracking geometries, and methods which may be suitable for use, for example, with silicon or other PV cells. In one-dimensional CPV, sunlight is focused approximately to a line or lines, rather than to a spot or spots as occurs with a two-dimensional CPV system.

In one aspect, a concentrating solar energy collector comprises an elongated solar receiver comprising one or more photovoltaic cells and an elongated Fresnel reflector having a long axis oriented parallel to a long axis of the receiver and arranged to reflect solar radiation to the photovoltaic cells when the Fresnel reflector and the solar receiver are oriented such that the sun lies in or approximately in a plane defined by an optical axis of the Fresnel reflector and a long axis of the receiver. The Fresnel reflector comprises a plurality of elongated reflective elements fixed with respect to each other and with respect to the receiver and having long axes oriented parallel to the long axes of the Fresnel reflector and the receiver. The long axes of the reflective elements lie on or approximately on a parabola.

The concentrating solar energy collector of this aspect may further comprise a rotation mechanism allowing the receiver and Fresnel reflector to be oriented to track the sun. In one variation, the rotation mechanism allows azimuthal rotation of the receiver and the Fresnel reflector. In another variation, the rotation mechanism allows the receiver and the Fresnel reflector to be rotated about a North-South axis, or about an approximately North-South axis, to track East-West motion of the sun. In yet another variation, the rotation mechanism allows the receiver and the Fresnel reflector to be rotated about an East-West axis, or about an approximately East-West axis, to track North-South motion of the sun.

In any of the above variations of this aspect, the reflective elements may have widths transverse to their long axes of about 5% to about 10% of a width of the Fresnel reflector transverse to its long axis, for example. Other widths for the reflective elements may also be used.

In any of the above variations of this aspect, the receiver may have a “V”-shape cross-section, or an approximately “V”-shape cross-section, in a plane transverse to its long axis. The angle between the arms of the “V” may be, for example, about 90°, though larger or smaller angles may also be used. For example, the solar receiver may include first and second elongated solar cell arrays arranged side-by-side lengthwise and inclined with respect to each other about their respective long axes to form a “V” shape or approximately “V” shape with apex pointed toward the reflector.

In any of the above variations of this aspect, the reflective elements may be arranged to stagger their ends, to stagger gaps between adjacent collinear or approximately collinear reflective elements, or both.

In any of the above variations of this aspect, the photovoltaic cells may be liquid-cooled by, for example, a liquid (e.g., water) flowed length-wise through the receiver.

In another aspect, a concentrating solar energy collector comprises an elongated liquid-cooled solar receiver comprising one or more photovoltaic cells and an elongated reflector having a long axis oriented parallel to a long axis of the receiver and arranged to reflect solar radiation to the photovoltaic cells when the reflector and the solar receiver are oriented such that the sun lies in or approximately in a plane defined by an optical axis of the reflector and a long axis of the receiver. The receiver has a “V”-shaped cross-section, or an approximately “V”-shaped cross-section, in a plane transverse to its long axis. The angle between the arms of the “V” may be, for example, about 90°, though larger or smaller angles may also be used. For example, the solar receiver may include first and second elongated solar cell arrays arranged side-by-side lengthwise and inclined with respect to each other about their respective long axes to form a “V” shape or approximately “V” shape with apex pointed toward the reflector. Liquid cooling of the photovoltaic cells in the receiver may be by, for example a liquid (e.g., water) flowed length-wise through the receiver.

The concentrating solar energy collector of this aspect may further comprise a rotation mechanism allowing the receiver and Fresnel reflector to be oriented to track the sun. In one variation, the rotation mechanism allows azimuthal rotation of the receiver and the Fresnel reflector. In another variation, the rotation mechanism allows the receiver and the Fresnel reflector to be rotated about a North-South axis, or about an approximately North-South axis, to track East-West motion of the sun. In yet another variation, the rotation mechanism allows the receiver and the Fresnel reflector to be rotated about an East-West axis, or about an approximately East-West axis, to track North-South motion of the sun.

In any of the above variations of this aspect, the reflector may have a parabolic or approximately parabolic cross-section transverse to its long axis.

In any of the above variations of this aspect, the reflector may comprise a plurality of elongated reflective elements fixed with respect to each other and with respect to the receiver and having long axes oriented parallel to the long axes of the reflector and the receiver. The reflective elements may optionally be arranged to stagger their ends, to stagger gaps between adjacent collinear or approximately collinear reflective elements, or both.

In another aspect, a concentrating solar energy collector comprises an elongated solar receiver comprising one or more photovoltaic cells and an elongated Fresnel reflector having a long axis oriented parallel to a long axis of the receiver and arranged to reflect solar radiation to the photovoltaic cells when the Fresnel reflector and the solar receiver are oriented such that the sun lies in or approximately in a plane defined by an optical axis of the Fresnel reflector and a long axis of the receiver. The Fresnel reflector comprises a plurality of elongated reflective elements fixed with respect to each other and with respect to the receiver and having long axes oriented parallel to the long axes of the Fresnel reflector and the receiver. The reflective elements are arranged to stagger their ends, to stagger gaps between adjacent collinear or approximately collinear reflective elements, or both.

The concentrating solar energy collector of this aspect may further comprise a rotation mechanism allowing the receiver and Fresnel reflector to be oriented to track the sun. In one variation, the rotation mechanism allows azimuthal rotation of the receiver and the Fresnel reflector. In another variation, the rotation mechanism allows the receiver and the Fresnel reflector to be rotated about a North-South axis, or about an approximately North-South axis, to track East-West motion of the sun. In yet another variation, the rotation mechanism allows the receiver and the Fresnel reflector to be rotated about an East-West axis, or about an approximately East-West axis, to track North-South motion of the sun.

In any of the above variations of this aspect, the photovoltaic cells may be liquid-cooled by, for example, a liquid (e.g., water) flowed length-wise through the receiver.

In any of the above variations of any of the above aspects, solar radiation may be concentrated on the receiver to, for example, approximately 5 to approximately 20 “suns” or approximately 10 to approximately 20 “suns.” Higher or lower concentrations may also be used

In any of the above variations of any of the above aspects, the photovoltaic cells may comprise silicon photovoltaic cells.

Commercial (e.g., rooftop) and/or large-scale installations may benefit from the systems, apparatus, geometries, and methods disclosed herein. One-dimensional concentration to approximately 5-20 or approximately 10-20 “suns” of intensity in some variations, for example, may achieve significant cell-area-reduction advantages without demanding the tight tolerance control or complex motions that are inherent to higher concentration CPV systems. The disclosed systems, apparatus, geometries, and methods may, in some variations, result in a low fabrication cost (expressed, e.g., in $/Watt of capacity). In addition, some variations may support flexibility in installation size, fabrication at a high-volume assembly facility, easy transport and installation, and/or efficient use of widely available commodity components that can be manufactured in effectively unlimited quantities.

Use of silicon photovoltaic cells in some variations may offer advantages including a mature supply-chain, availability, robustness, efficiency (e.g., ˜20% or more solar to electrical power conversion), and the ability to operate with incident power densities of 10-20 “suns”, or greater. In variations with optical concentration exceeding ˜5 “suns”, the moderate cost of silicon cells may become a low-to-insignificant cost.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 shows the position of the sun during the course of a day expressed in Polar (azimuthal and inclination angle) coordinates.

FIG. 2 shows the position of the sun during the course of a day expressed in Cartesian (East-West and North-South angle) coordinates.

FIG. 3 shows an example reflector/receiver assembly.

FIG. 4 shows another example reflector/receiver assembly.

FIG. 5 shows another example reflector/receiver assembly.

FIG. 6 shows a plan view of another example reflector/receiver assembly.

FIG. 7 shows another example reflector/receiver assembly.

FIG. 8 shows another example reflector/receiver assembly.

FIG. 9 shows an example reflector/receiver assembly mounted on an example rotation mechanism.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention, including what is presently believed to be the best mode of carrying out the invention.

As used in this specification and the appended claims, the singular forms “a,” “an,” and “the” include plural referents unless the context clearly indicates otherwise. Also, the term “parallel” is intended to mean “substantially parallel” and to encompass minor deviations from parallel geometries rather than to require that parallel rows of reflectors, for example, or any other parallel arrangements described herein be exactly parallel.

Disclosed herein are systems, apparatus, concentrating geometries, tracking geometries, and methods by which solar energy may be collected to provide, for example, electricity. The concentrating geometries and tracking geometries may be better understood in view of the following discussion of coordinate systems for tracking the position of the sun.

It is well known that the sun's motion is 2-dimensional, as viewed from a fixed location on the Earth's surface. Over the course of a year, the sun moves in a daily arc that reaches higher in the sky during summer months than during the winter. This motion can be described in various ways, including Cartesian (East-West angle and North-South angle) or Polar (azimuth angle and inclination angle) coordinate systems. The natural coordinate system to consider depends on the architecture (mechanical and optical geometry) of the CPV system.

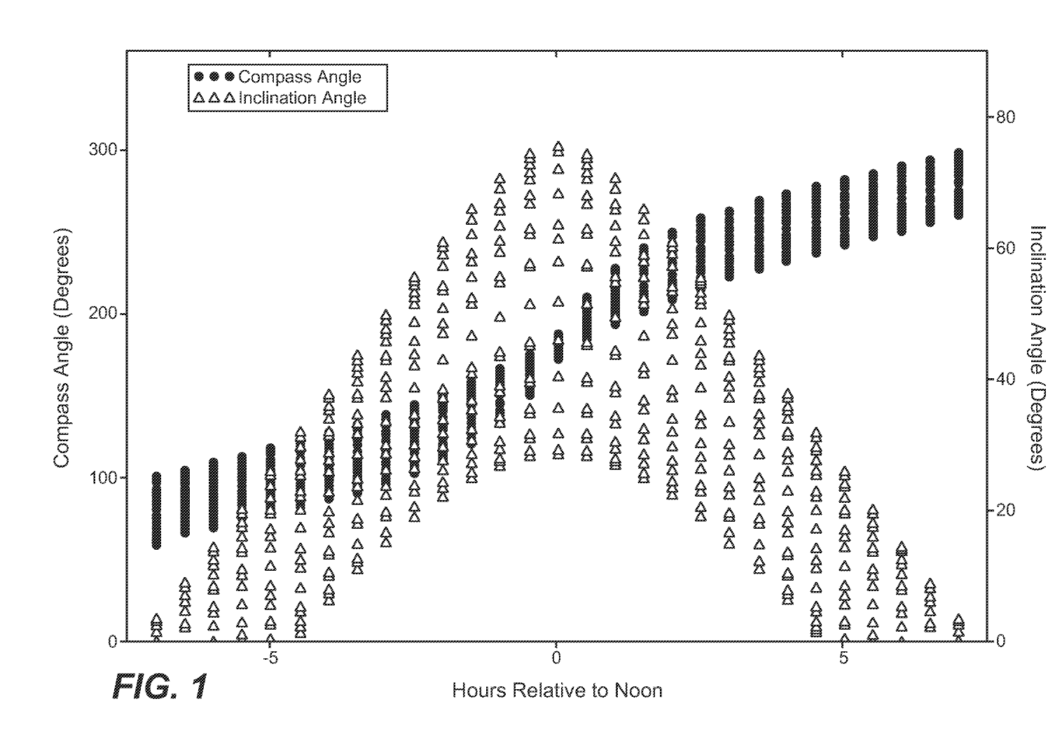

FIG. 1 shows the position of the sun (for each of the 12 months of the year, and every 30 minutes) expressed in Polar coordinates. The horizontal axis indicates the time of day, expressed in hours before or after “solar noon”, which is the time that the sun is highest overhead. There are two vertical axes. The left axis is the azimuthal (or compass) angle, which is plotted using dots. Zero degrees is due-North, 90 degrees is due-East, 180 degrees is due South, and 270 degrees is due-West. The right axis is the inclination angle, which is plotted using triangles. Zero degrees indicates sunrise or sunset, and 90 degrees indicates directly-overhead sun. This example graph was calculated for a latitude of 38 degrees North. Note that the sun is never directly overhead, though it does reach ˜80 degrees above the horizon. The Polar coordinate system for analyzing the sun's motion is most appropriate for system architectures including a mechanical azimuthal rotation.

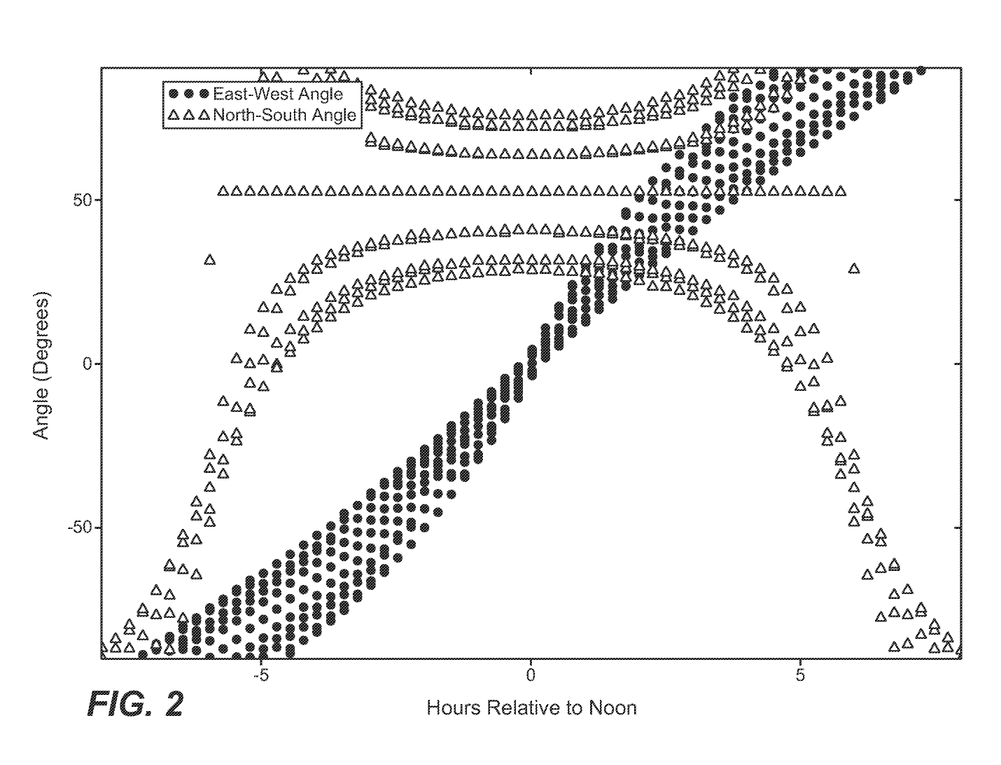

FIG. 2 shows the position of the sun (for each of the 12 months of the year, and every 30 minutes) expressed in Cartesian coordinates. As before, the horizontal axis indicates the time of day, expressed in hours before or after “solar noon”, which is the time that the sun is highest overhead. In this graph, there is only one vertical axis, for both the East-West (plotted using dots) and North-South (plotted using triangles) angles. Note that the East-West angle spans the full −90 to +90 degrees (sunrise to, sunset), while the North-South angle spans a smaller range. This example graph was also calculated for a latitude of 38 degrees North. Note that, at sunrise and sunset, the North-South angle can swing very far to the South, but that near midday, the North-South angle remains near the latitude of the observer. Also note that the sun traverses a narrower total range of North-South angles near the equator, and a larger range of North-South angles at higher latitudes. The Cartesian coordinate system for analyzing the sun's motion is appropriate for system architectures not including a mechanical azimuthal rotation.

While the sun's motion is two-dimensional, a one-dimensional CPV system as disclosed herein may utilize either one-dimensional or two-dimensional tracking of the sun. The tracking may match either a Polar or a Cartesian coordinate system, for example. The tracking can be implemented, for example, using PV cell motion, mirror motion, or both.

A useful way to understand one-dimensional concentration is to first note that a linear PV cell array (e.g., in a linear solar receiver) and the optical center line (optical axis) of an elongated (e.g., flat or cylindrical) mirror oriented parallel to the linear PV cell array define a plane. If the sun lies in this plane, then the sun's rays are focused into a line that is collinear with the PV cell array. The length of this focused line is determined by the length of the mirror. This focused line can be longer than, equal to, or shorter than the length of the PV cell array. This focused line can also be displaced relative to the PV cell array along the long axis of the PV cell array. The displacement depends on the angle defined by the sun and the surface normal of the mirror, as well as the relative position of the mirror and the PV cells. It may be most efficient to minimize this displacement.

It may be desirable that the CPV system tracks the sun in at least one dimension, so as to assure that the sun does lie in the symmetry plane of the mirror and the PV cell array. An additional dimension of tracking can (optionally) eliminate the displacement between the focused line of sunlight and the PV cell array. If two tracking dimensions are used they may, for example, be perpendicular or nearly perpendicular to each other.

Several factors can influence the significance of the relative displacement between the focused line of sunlight and the PV cells. It may be important to minimize the ratio of the relative displacement to the length of the PV cells, as this ratio represents a potential loss factor. The relative displacement depends in part on at least two factors: (1) the height of the PV cells above the mirror, and (2) the angular range of solar motion that is not tracked by the CPV system. Hence, the impact of relative displacement may be minimized by, for example: (1) minimizing the cell height, (2) maximizing the mirror/cell length, and (3) selecting a configuration that minimizes the angular range of non-tracked solar motion.

### Tracking and Concentrating Configurations

Various configurations that may be used for orientation of the concentration and the tracking directions in systems, apparatus, and methods disclosed herein include those described below.

Azimuthal concentration (1D tracking). This configuration may utilize azimuthal (1-D) tracking without any additional tracking. For example, a concentrating mirror/s and PV cell assembly (e.g., receiver) can be fixed onto a rotation mechanism (e.g., turntable), such that both reflector and cells rotate together. One-dimensional (azimuthal) rotation of the mirrors and PV cell assembly may assure that the sun lies in or near the plane defined by the mirror optical centerline and the PV cells. With this form of tracking, sunlight focuses to a North-South line at noon. As the inclination of the sun changes (e.g., roughly zero degrees at sunrise/sunset, up to roughly 90 degrees at noon at the edge of the tropics) the system may suffer a displacement penalty driven by <90 degrees of non-tracked solar motion. The turntable or other rotation mechanism may be oriented horizontal with respect to the ground (i.e., rotating about a vertical axis) or, alternatively, inclined with respect to the ground. The mirror and PV cells may be mounted perpendicular to the rotation axis or, alternatively, inclined at an angle to the rotation axis. An inclined rotation axis or mounting geometry may provide greater solar collection per unit of mirror area and PV cell length, though possibly at a cost of increased mechanical complexity and wind exposure.

Azimuthal concentration (2D tracking). This configuration may be implemented with both azimuthal and inclination tracking. For example, a concentrating mimes assembly can be fixed onto a rotation mechanism (e.g., a turntable). A PV cell assembly (e.g., a receiver) is also attached to the turntable, but can be translated along its axis to compensate for changes in the inclination of the sun. Any suitable translation mechanism may be used to translate the PV cell assembly along its axis. One-dimensional (azimuthal) rotation of the mirrors and PV cell assembly may assure that the sun lies in or near the plane defined by the mirror centerline and the PV cells. The turntable or other rotation mechanism may be oriented horizontal with respect to the ground (i.e., rotating about a vertical axis) or, alternatively, inclined with respect to the ground. The mirror and PV cells may be mounted perpendicular to the rotation axis or, alternatively, inclined at an angle to the rotation axis. An inclined rotation axis or mounting geometry may provide greater solar collection per unit of mirror area and PV cell length, though possibly at the cost of increased mechanical complexity and wind exposure.

Azimuthal concentration (2D tracking, alternate configuration). Similar to the above configuration, a single linear motion of the mirror (as opposed to the cells/receiver) may be used to compensate for changes in the inclination of the sun. Any suitable translation mechanism may be used to translate the mirror along its axis. The turntable or other rotation mechanism may be oriented horizontal with respect to the ground (i.e., rotating about a vertical axis) or, alternatively, inclined with respect to the ground. The mirror and PV cells may be mounted perpendicular to the rotation axis or, alternatively, inclined at an angle to the rotation axis. An inclined rotation axis or mounting geometry may provide greater solar collection per unit of mirror area and PV cell length, though possibly at the cost of increased mechanical complexity and wind exposure.

Inclination concentration. This configuration may utilize both azimuthal and inclination (2-D) tracking. For example, a PV cell assembly can be fixed onto a rotation mechanism (e.g., a turntable), while a movable concentrating mirror/s assembly is also placed onto the same rotation mechanism/turntable. As with the “azimuthal concentration” approach, one (azimuthal) rotation may assure that the sun lies in or near the plane defined by the mirror centerline and the PV cells. However, in this configuration and with this form of tracking the PV cells and the mirror are oriented such that, at noon, sunlight is focused to an East-West line. As the inclination of the sun changes (zero degrees at sunrise/sunset, up to 90 degrees at noon) the mirrors move to track this inclination change, reducing or eliminating any relative displacement penalty. The turntable or other rotation mechanism may be oriented horizontal with respect to the ground (i.e., rotating about a vertical axis) or, alternatively, inclined with respect to the ground. The mirror and PV cells may be mounted perpendicular to the rotation axis or, alternatively, inclined at an angle to the rotation axis. An inclined rotation axis or mounting geometry may provide greater solar collection per unit of mirror area and PV cell length, though possibly at the cost of increased mechanical complexity and wind exposure.

As compared with the “azimuthal concentration” approach, this approach may increase complexity (to accomplish 2D tracking), but may reduce or eliminate any relative displacement penalty. Hence, the PV cells may be placed at any convenient height, without regard for displacement penalty. Increasing the height of the PV cells may reduce the cost, optical losses, and wind-loading associated with the concentrating mirror. As compared with the “East-West concentration” and “North-South concentration” approaches described below, this approach reduces the angular range of the sun's motion to be tracked. Essentially, a large angular range (and simple) azimuthal rotation combines with a small angular range inclination motion to achieve 2D tracking.

East-West concentration. This configuration may utilize East-West (1-D) tracking, without any other tracking. For example, a fixed PV cell assembly (e.g., receiver) may be combined with a moving mirror/s assembly that tracks the East-West motion of the sun. Alternatively, the PV cell assembly and mirror's assembly may move together (e.g., be fixed with respect to each other) to track the East-West motion of the sun. With this form of tracking, at all times of day sunlight focuses to a (or an approximately) North-South line. As the North-South orientation of the sun changes the system will suffer a displacement penalty driven by >90 degrees of non-tracked solar motion. As can be seen from the figures above, the North-South angular motion (Cartesian coordinate system) is much greater than the inclination angular motion (Polar coordinate system). Hence, this approach may lead to a greater relative displacement penalty than the “Azimuthal concentration” approach.

North-South concentration. This configuration may utilize North-South (1-D) tracking, without any other tracking. For example, a fixed PV cell assembly (e.g., receiver) may be combined with a moving mirror's assembly that tracks the North-South motion of the sun. Alternatively, the PV cell assembly and mirror's assembly may move together (e.g., be fixed with respect to each other) to track the North-South motion of the sun. With this form of tracking, at all times of day sunlight focuses to an (or an approximately) East-West line. As the East-West orientation of the sun changes the system will suffer a displacement penalty driven by 180 degrees of non-tracked solar motion. Hence, this approach may lead to a greater relative displacement penalty than any of the alternatives. However, the total range of tracked angle may be smaller than that of the “East-West concentration” approach.

### Additional Optical Considerations

In addition to the tracking factors described above, several additional optical considerations may influence performance. Mirror reflectivity presents a fundamental loss mechanism for any of the 1-D concentration architectures described herein. Typical mirror reflectivities may be ˜90 to ˜95% for low-cost mirrors. If the reflector is faceted or of Fresnel type (described below), there may be a small (e.g., <10%) amount of loss caused by light that reflects from one facet of the mirror, but is then blocked by the back surface of an adjacent facet. This loss mechanism may become more significant when a Fresnel mirror is used with high numerical aperture (short focal length or low cell height, as compared with the mirror aperture) and/or when the mirror may be used for a variety of angles of incidence in the concentrating dimension. As the degree of concentration is increased (i.e. the total cell area, for a fixed collection aperture, is reduced), the tolerances get more difficult. Tolerances for most of the mechanical structure may be, for example, roughly 10% of the cell width. A portion of the mirror may be shadowed by the cell itself as well as its support structure. This factor becomes more important for concentration less than ˜10 “suns”.

### Additional Variations

The additional features and combinations of features described below may be used in any suitable combination with each other and with those described above in the “Tracking and Concentrating Configurations” section.

Fresnel mirror versus continuous mirror. The reflecting surface could be implemented with any number of reflecting elements. Some variations may utilize a single parabolic trough. Alternately, a pair of half-troughs may be utilized. The half-troughs may be less expensive to fabricate, due to reduced size (and, e.g., 5-10% reduced total mirror area, as the cells/receiver may shadow a portion of the center of a single trough). A Fresnel-style reflector with many reflecting elements may also be used. A Fresnel reflector allows for a reduced system height, and reduced wind loading. However, a Fresnel reflector may suffer from vignetting losses. These losses may be small when the Fresnel reflector is used at a fixed angle of incidence (as with the “azimuthal concentration (1D tracking)” approach.)

Fresnel mirror: flat versus curved elements. In some variations a Fresnel mirror using N flat reflecting elements is employed. Such a Fresnel mirror provides a maximum concentration of N “suns.” In other variations, some or all of the reflecting elements of the Fresnel reflector may be curved. With curved (focusing) mirror elements, additional concentration can be achieved. Depending on fabrication methods, there may be a cost advantage to flat elements.

On ground/earth versus rooftop. The apparatus and systems described herein may be located on roof tops in some variations, and at or near ground level in other variations. Low cost and high-efficiency may enable their use in large-scale installations in some variations.

Near-flat Fresnel-mirror versus near-parabolic Fresnel mirror. A reflecting Fresnel surface could be implemented in various ways, though the common feature is a plurality of distinct (flat or curved) reflecting sub-elements. The most basic parameter is the number of reflecting sub-elements. If the reflecting sub-elements are flat, the size of the mirrors sets a minimum size for the concentrated light area and hence sets a minimum illuminated area for the receiver/PV cells and a maximum amount of concentration for the system. An additional parameter that is important in arranging a Fresnel mirror is the elevation of the off-center mirror sub-elements.

In some variations, the reflective sub-elements may be arranged with their centerlines coplanar. This minimizes the height of the structure, which may reduce mechanical support cost and help to reduce the range of angles of incidence of light reflected to the receiver. This design may suffer from a loss mechanism whereby light reflected from one mirror sub-element may intersect the back surface of an adjacent mirror. If the mirrors are spaced apart to avoid this loss mechanism, then some incident sunlight may not be intercepted by the Fresnel reflector.

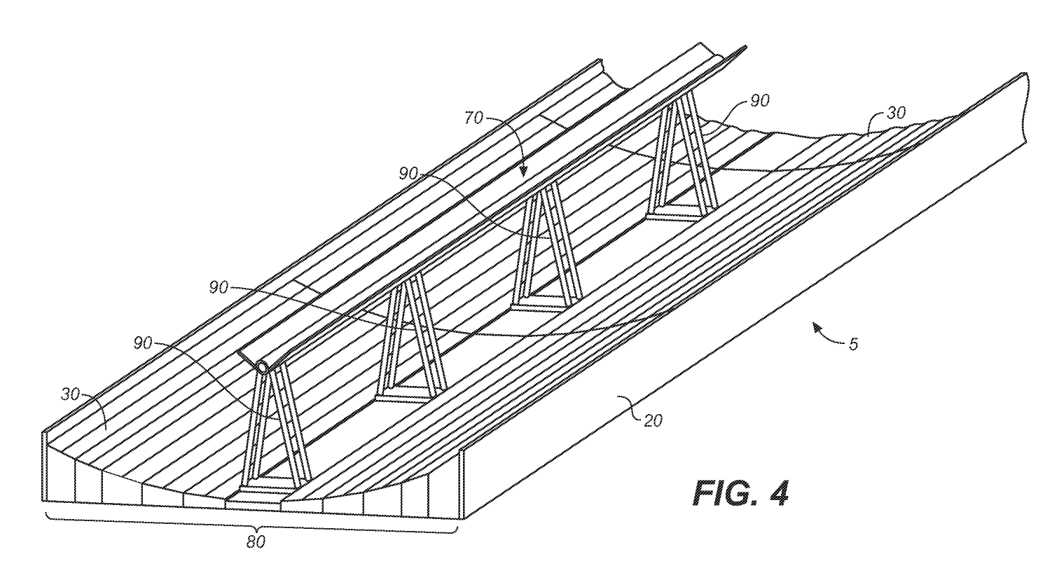

In other variations, the mirror sub-elements may be arranged with their centerlines on or approximately on a parabolic trough. (See, for example, FIGS. 4, 5, 7, and 8 described below). In these variations, the Fresnel mirror forms a piecewise approximation to the (curved) parabolic trough that would focus onto a receiver at the same location. The Fresnel mirror in these variations may be viewed as an aberrated parabolic mirror. An advantage of this design is that there is little or no loss due to light reflected from one mirror sub-element intersecting the back surface of an adjacent mirror. A possible disadvantage of this design is that the overall reflector height is increased. This may increase mechanical support costs and also increase the range of incidence angles on the receiver.

In yet other variations, the sub-elements of a Fresnel reflector may be arranged to form reflective troughs having a cross-sectional shape differing from a parabola. These shapes may be, for example, intermediate between a flat mirror and a parabolic trough.

Methods to avoid non-uniform illumination and shadowing of the receiver. With photovoltaic systems, it may be important that all cells within the PV array that are connected in electrical series be illuminated with a nearly identical total optical power. This is because the current generated by series connected PV cells is limited by the least-illuminated cell within the series. As an example, if an array containing 100 cells connected in series has one cell in partial shadow and thereby receiving only 90% of the solar flux as the remaining cells, then the entire series will produce only 90% of its potential electrical power, even though it intercepts 99.9% of its potential solar flux.

In some variations, the PV cells (e.g., receiver) may be positioned above the reflector by a support structure. The cells (e.g., receiver) and the support structure may cast shadows on the PV cells. Such shadows can be caused either by shadowing of sunlight before it hits the reflector, or by shadowing of sunlight after it has been reflected from the reflector towards the receiver. The shadows may move through the day as the sun moves across the sky and as the reflector and/or receiver move to track the sun. The size, number, and/or affect of the shadows may be reduced in several variations.

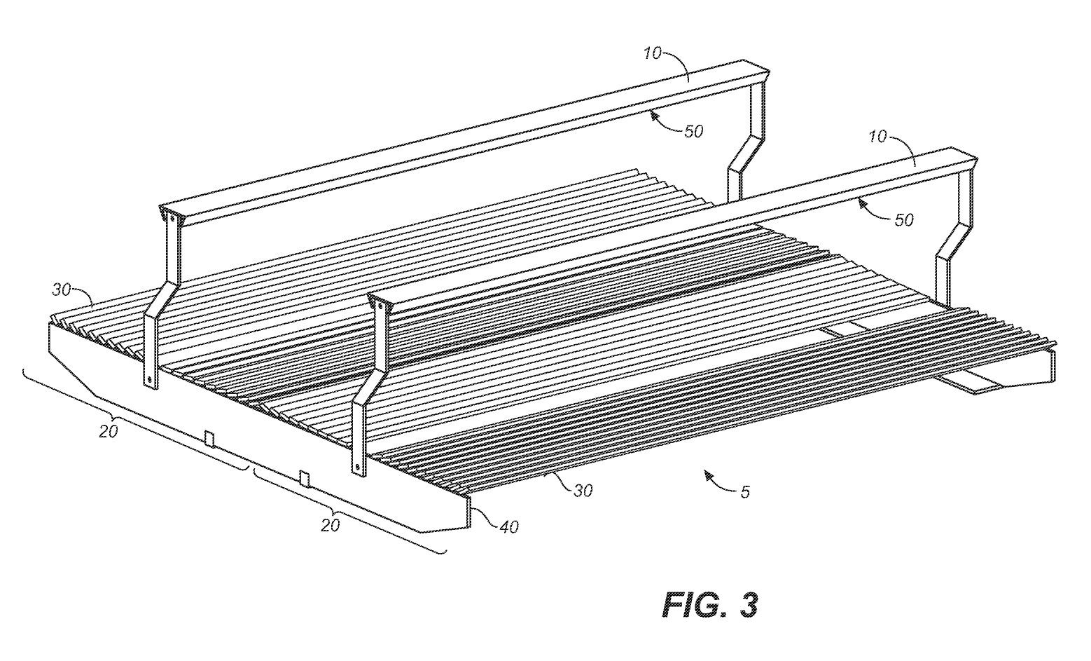

In some variations, the reflector and receiver are designed and/or arranged so that reflected rays of sunlight do not cross the centerline in their path to the PV cells. This may reduce or eliminate shadowing by the support structure of light reflected from the reflector to the receiver. For example, in some variations the receiver includes two sets of PV cells, one of which receives reflected light from the reflector on one side of the receiver, and the other of which receives reflected light from the reflector on the other side of the receiver. (See, for example, FIGS. 3, 4, and 9 described below). Some of these variations may utilize substantial, (possibly opaque) central support or supports to support the receiver above the reflector. The width of the supports in some variations may be, for example greater than ˜5%, ˜10%, ˜25%, ˜50%, or ˜100% of the width of a PV cell.

In other variations, a mostly-open central support that generates a tolerable shadow (e.g., less than ˜5% of the cell width) may be used to set the distance between the receiver and the center of the mirror. Additional guy (tension) wires between the receiver and the two top-edges of the reflector may be used to hold the receiver stable. The guy wires may generate a negligible shadow, and may support the weight of the receiver when the reflector/receiver is oriented with gravity pointing away from the centerline as it tracks the sun. The strength of the central support need not be greater than that necessary to avoid buckling. In some variations the central support generates such a tolerable shadow and is sufficiently strong that such guy wires are not used.

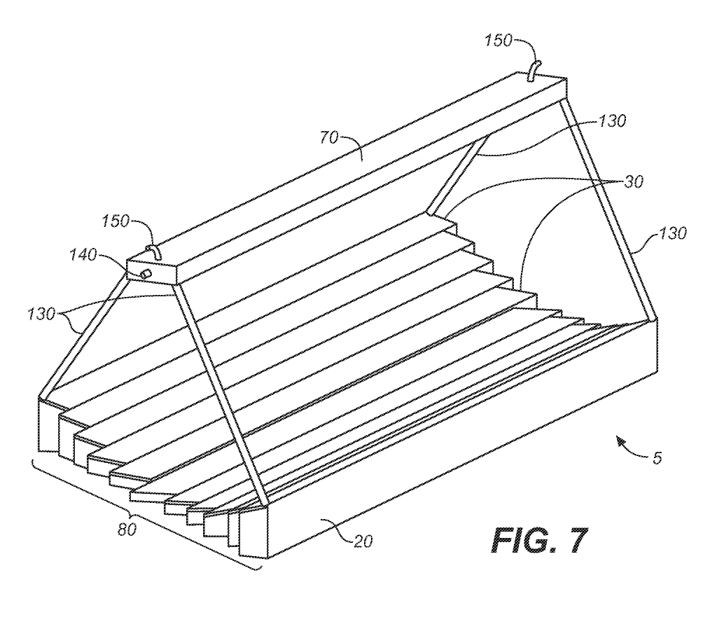

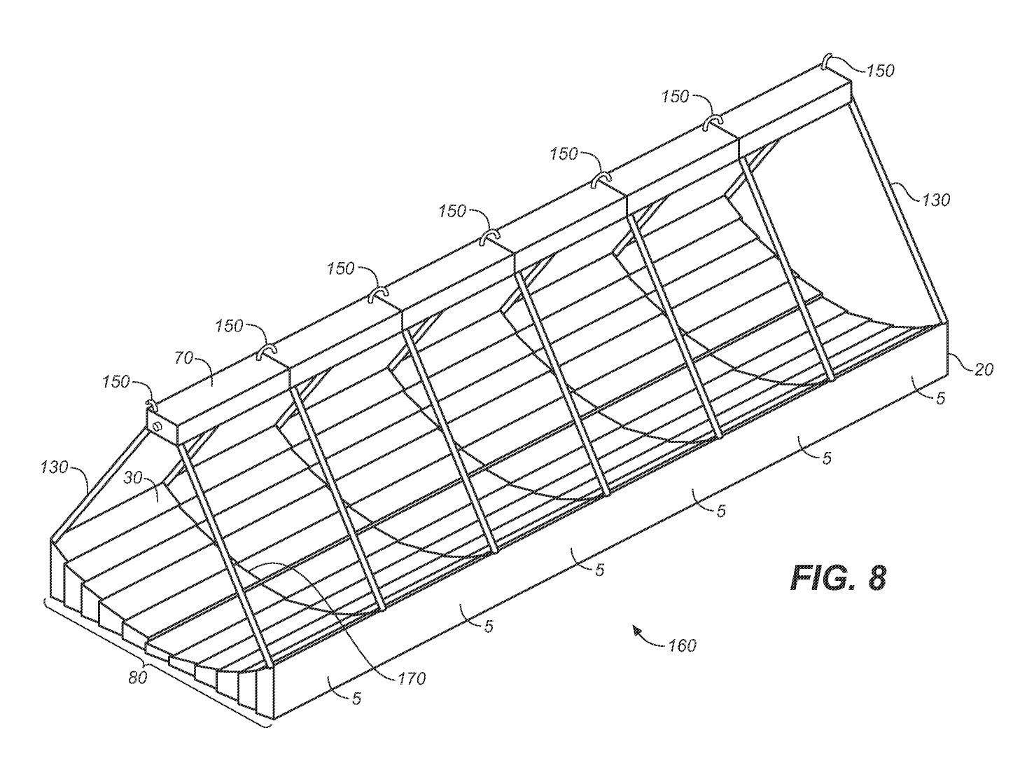

In other variations, the reflector, receiver, and support structure supporting the receiver above the reflector form an approximately triangular structure. (See, for example, FIGS. 7 and 8 described below). In these variations, periodic rigid supports connect the top (i.e., outer) edges of the reflector to the receiver from either side of the receiver. These supports may be, for example, thick and/or rigid enough to avoid buckling, but not so large as to produce a shadow that is a significant fraction of a PV cell. For example, the supports may be sufficiently thin such that the shadows they cast on the mirror, when reflected to the receiver, cover less than ˜5%, ˜7%, or ˜10% of the width of a PV cell.

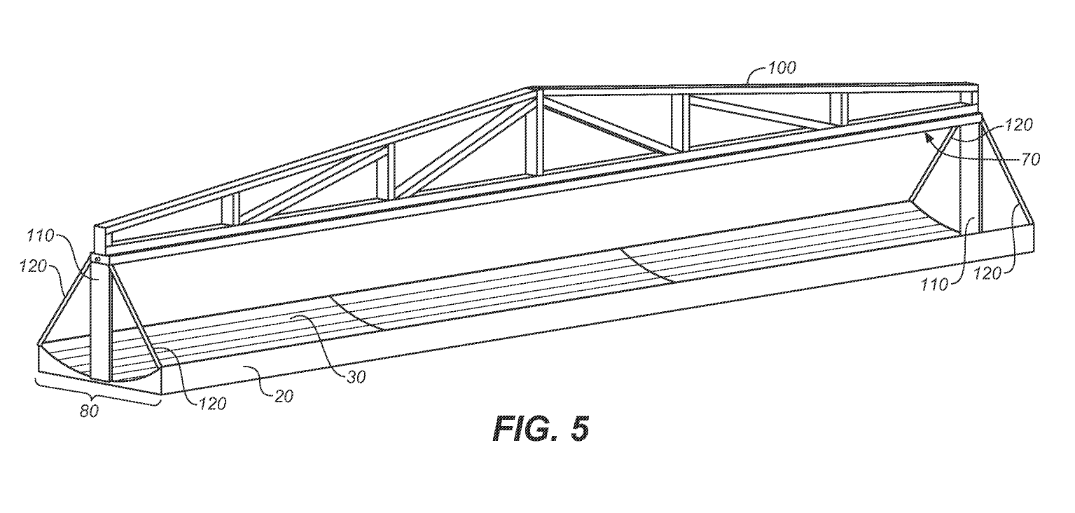

In other variations, the receiver may be supported from a structure that is entirely above the receiver except for one or more supports on either end of the receiver. (See, for example, FIG. 5 described below). Shadowing may be avoided in some variations by extending the support structure beyond the ends of the reflector and placing end supports sufficiently far from the reflector.

In addition to shadows on the PV cells caused by the support structure that positions the receiver with respect to the reflector, there can also be “effective” shadows caused by the gaps between two sections of reflector. For example, if a system (e.g., reflector and receiver) is 18 meters long, the reflector may be made from six mirror sections each of which is three meters in length. Between each of those sections, there may be a small gap (e.g., to allow for thermal expansion and/or assembly tolerances). These gaps will not reflect/concentrate sunlight; hence dark “shadows” may result on the receiver. Also, if the focal line of the reflector is displaced along the receiver, the end of the reflector (or ends of the reflector sub-elements) may define an edge of an effective shadow on the receiver resulting from that displacement. In either ease, as the sun moves the shadow may move, creating a time-varying non-uniformity on the PV cells.

In some variations, the affect of these “effective” shadows may be reduced by arranging the sub-elements in a Fresnel reflector to stagger the positions of the gaps between mirror sections (or sub-elements) and/or to stagger the positions of the ends of Fresnel reflector sub-elements. This spreads the “effective” shadows along the receiver (e.g., across several PV cells) and consequently reduces the magnitude of the non-uniformity, which may improve overall system efficiency.

Motion of the reflector and/or receiver. Either or both of the reflector and/or receiver may move to track solar motion. The reflector may be closer to the ground, may not require electrical or cooling connections, and hence may be easier to move than the receiver. In some variations the reflector and receiver move together as a single unit to track the sun. This may reduce or minimize the range of incidence angles of sun light reflected to the receiver and may also allow for the full collection aperture of the reflector to be used at most or all times of the day. In some variations in which the reflector and receiver move together to track the sun, a rigid structure supports the reflector and the receiver together as a single unit, which is pointed towards the sun by a tracking system.

Cooling the PV cells. Many types of PV cells work more efficiently when operating near room temperature, or cooler. Operation at greater than 1 “sun” of intensity may heat PV cells to temperatures at which their efficiency declines. In some variations, the PV cells are air cooled (via finned heat sinks, for example) or water cooled. In water cooled variations, water inlet and outlet connections may be made, for example, at opposite ends of the receiver. Such connections may utilize, for example, a flexible “hose” with barb-type fittings, connecting pipes with o-ring seals, or bushing-type joints. In some variations it may be advantageous to minimize the number of water connections by lengthening the receiver.

Modules. Some variations may utilize integrated modular panels that include a (e.g., one to three meter, or greater than three meter) length of reflector, receiver, and receiver support structure. The modules may also include provision for air or water cooling the PV cells. These modules may be assembled into larger systems (e.g., at the site of use) with appropriate electrical, water, and structural connections and opto-mechanical alignments made or performed as necessary. Such a scalable approach utilizing integrated modules may be advantageous. For example, such modules may, in some variations, be manufactured in high volume and assembled into systems with little or minimal on-site labor. In some variations, the modules may be installed on a variety of tracking systems. One example is a very large azimuthal tracker supporting a large array of modular panels. In some variations modules includes all features necessary for connection/alignment to and with other modules.

### EXAMPLES

The features and combinations of features described with respect to the examples below may be used in any suitable combination with each other and with those described above in the “Tracking and Concentrating Configurations” and “Additional Variations” sections.

Referring now to FIG. 3, an example reflector/receiver assembly (e.g., module) 5 comprises solar receivers 10 and concentrating Fresnel reflectors 20 (comprising reflector elements 30) mounted to a common support 40. The concentrating reflectors 20 focus solar radiation from the sun one-dimensionally (i.e., approximately to lines or to linearly extended spots) onto elongated receivers 10. In the illustrated example, each receiver has a “V” or triangle shape with PV cells 50 mounted on the downward facing sides to receive reflected sunlight from opposite sides of the receiver. Although the illustrated example includes two receivers 10 and two reflectors 20, in other variations reflector/receiver assembles (e.g., modules) may include only one receiver and one reflector, or include more than two receivers and more than two reflectors.

Each Fresnel reflector may comprise, for example, about 20 reflector elements with about 10 reflector elements on each side of the corresponding receiver. A central reflector element may be omitted (because it may be shadowed by the receiver). The reflector elements are angled to concentrate sunlight on the receivers. Individual reflector elements in each Fresnel reflector may be angled at slightly different inclinations with respect to each other in order to concentrate sunlight onto solar cells located on opposite sides of the V-shaped receiver.

Referring now to FIG. 4, another example reflector/receiver assembly (e.g., module) 5 comprises a V-shaped receiver 70 supported above a single Fresnel reflector 80 (comprising reflector elements 30) by central supports 90. Receiver 70 comprises PV cells 50 mounted on its downward facing sides to receive reflected sun light from opposite sides of the receiver. If reflector/receiver assembly 5 is oriented so that the sun lies in or approximately in a plane defined by receiver 70 and an optical axis of Fresnel reflector 80, little or no reflected light crosses that plane and central supports 90 produce little or no shadow on PV cells 50. Reflector elements 30 may be arranged with their centerlines on or approximately on a parabolic trough.

Referring now to FIG. 5, another example reflector/receiver assembly (e.g., module) 5 comprises a receiver 70 supported above a Fresnel reflector 80 (comprising reflector elements 30) from above by upper support structure (e.g., truss) 100 and vertical supports 110. Vertical supports 110 are optionally braced by cross-braces 120. The width of upper support structure 100 is less than or approximately equal to that of receiver 70. If reflector/receiver assembly 5 is oriented so that the sun lies in or approximately in a plane defined by receiver 70 and an optical axis of Fresnel reflector 80, than upper support structure 100 cast no shadow on reflector 80 (it shadows only the back side of receiver 70). Cross braces 120 may be angled, in some variations, such that they only cast shadows on PV cells at the beginning and end of the day. Reflector elements 30 may be arranged with their centerlines on or approximately on a parabolic trough.

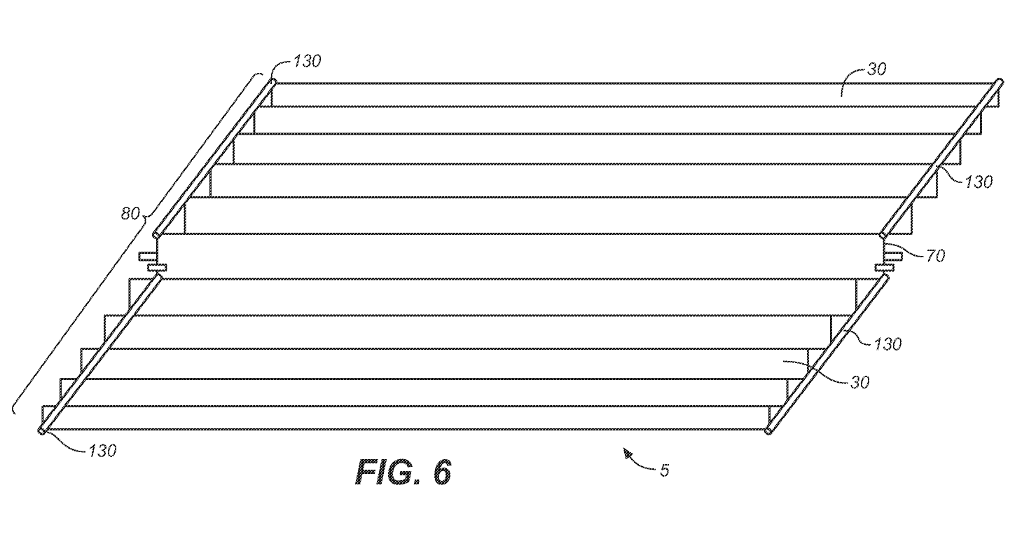

FIG. 6 shows a plan view of another example reflector/receiver assembly (e.g., module) 5 in which the positions of reflective sub-elements 30 of a Fresnel reflector 80 are (optionally) staggered. (Similar optional staggering of reflector sub-elements is also shown in FIGS. 4, 5, 7, and 8, although it is not as clear as in the plan view of FIG. 7). This arrangement may produce effective shadows on receiver 70, as described above, that span several PV cells, thereby reducing the impact of non-uniform illumination of the cells. FIG. 7 also shows supports 130 that support receiver 70 above Fresnel reflector 80.

Referring now to FIG. 7, another example reflector/receiver assembly (e.g., module) 5 comprises a receiver 70 (comprising PV cells, not shown) supported above a Fresnel reflector 80 (comprising reflector sub-elements 30) by narrow supports 130 that connect the top (i.e., outer) edges of reflector 80 to receiver 70 from either side of the receiver. In this example, reflector 80, receiver 70, and supports 130 form an approximately triangular structure. In the illustrated example, the positions of reflective sub-elements 30 are staggered as described above. This is not required, however. Electrical connections 140 and (optional) water connections 150 are located at each end of receiver 70. Reflector elements 30 may be arranged with their centerlines on or approximately on a parabolic trough.

FIG. 8 shows an example reflector/receiver assembly (or CPV system) 160 comprising six of the reflector/receiver assemblies (e.g., modules) 5 shown in FIG. 7 arranged end-to-end. Narrow supports 130 are placed periodically from the receiver 70 to the outer edges of the reflector array. Optional water fittings 150 are located at the ends of each module 5. The staggered positions of reflector sub-elements 30 stagger the gaps (e.g., gap 170) between reflector sub-elements in adjacent reflector/receiver assemblies (e.g., modules), spreading the effective shadow cast by these gaps on receiver 70. Reflector elements 30 may be arranged with their centerlines on or approximately on a parabolic trough.

Reflector/receiver assemblies (e.g., modules) as disclosed herein may be made compatible with many existing types of tracking systems. In some variations, reflector/receiver assemblies are installed on individual rotation mechanisms (e.g., turntables/trackers). In other variations, two or more reflector/receiver assemblies (e.g., an array of modules) may be installed on larger rotation mechanisms (e.g., turntables). Sharing rotation mechanisms (e.g., turntables) may allow for minimizing motor/controller costs, minimizing cooling costs, and also for minimizing module-to-module spacing. For example, in the concentration dimension, reflector/receiver assemblies may be installed adjacent to each other on an azimuthally tracking rotation mechanism without suffering significant optical losses (because of the azimuthal tracking.) In the non-concentration dimension, reflector/receiver assemblies can be installed on an azimuthally tracking rotation mechanism with a spacing that is limited by the tilt angle (which may be zero degrees -horizontal) of the reflector/receiver, and by the lowest sun inclination to be captured without shadowing losses.

In one example of azimuthal concentration with azimuthal tracking, one or more reflector/receiver assemblies (e.g., modules) each comprising one or more reflectors (e.g., reflective troughs) and one or more receivers comprising PV cells are mounted at an inclined angle (e.g., equal to or approximately equal to latitude) onto a turntable or other rotation mechanism that allows the module or modules to be rotated azimuthally to track the sun.

The reflector/receiver assemblies (e.g., modules) may be approximately 2.4 meters square, for example, and comprise one parabolic trough or (optionally) two side-by-side parabolic troughs. A linear receiver comprising PV cells may be positioned above the (or each) parabolic trough with the PV cells at a height, for example, of approximately 10% of the trough length (e.g., about 20 to about 30 centimeters if the troughs are about 2.4 meters long). In variations comprising two troughs in a 2.4 meter square module, each trough is about 1.2 meters wide and about 2.4 meters long. The PV cells may receive reflected sun light concentrated, for example, to between about 10 “suns” and about 20 “suns.” In some variations in which a 2.4 meter square module comprises two troughs and two receivers, the PV cells are about 10 centimeters wide and receive reflected light concentrated to about 11 “suns”. In other such variations, the PV cells are about 6 centimeters wide and receive reflected light concentrated to about 20 “suns”.

The receiver comprising the PV cells may be triangular or “V”-shaped, with a downward-facing apex and PV cells located on the two downward facing sides of the “V” or triangle. The apex angle may be, for example, about 90 degrees, so that each of the two halves of the PV cell receiver may be oriented at about a 45 degree angle to the axis of the trough. This arrangement may offer improved placement tolerances, reduced shadowing, and reduced cell height, as compared to a receiver comprising an equal area of PV cells located on a flat horizontal downward facing surface of a receiver.

In an example of inclination concentration with azimuthal and inclination tracking, one or more reflector/receiver assemblies (e.g., modules) each comprising an array of rotating mirrors and one or more receivers comprising PV cells are mounted on an azimuthally tracking turntable or other rotation mechanism. The individual mirrors may be rotated (e.g., at the same angular rate) to track the sun's inclination motion and concentrate sunlight in the inclination direction. Other aspects of this example may be the same or similar as those of the azimuthal concentration with azimuthal tracking example described above.

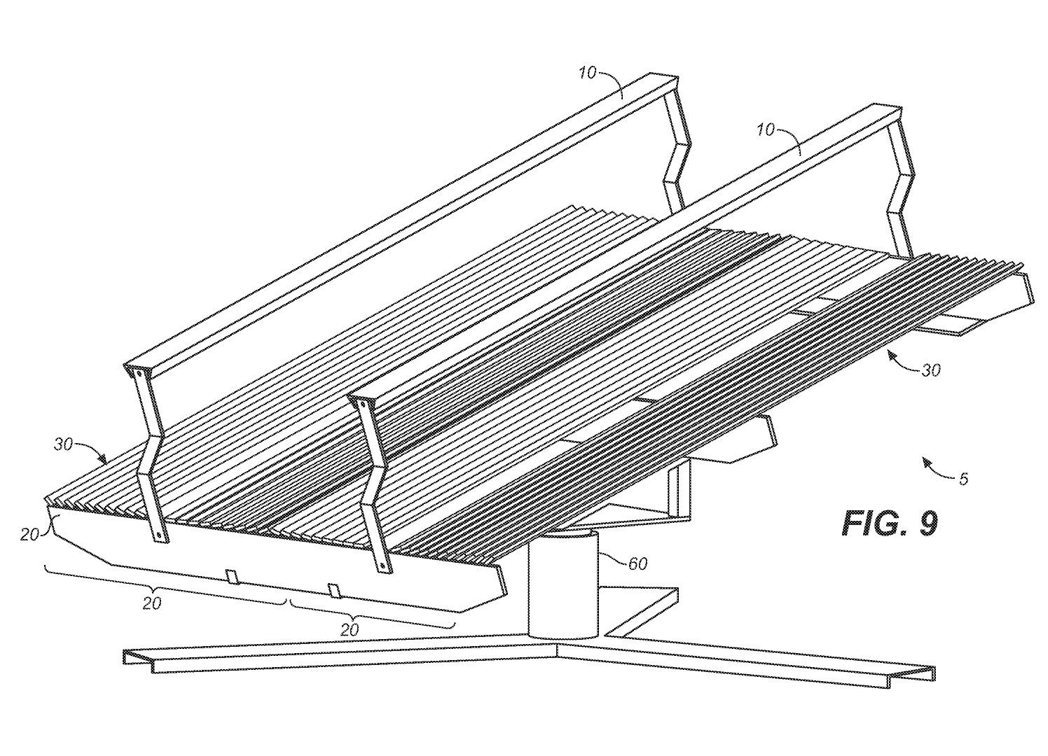

Referring now to FIG. 9, a reflector/receiver assembly (e.g., module) 5 as illustrated, or as described in any of the above examples, may be mounted to a rotation mechanism (e.g., rotating support or turntable) 60. Rotation mechanism 60 may be driven by a motor to rotate the Fresnel reflectors and receivers together. Any suitable solar tracking system may be used to control the motor to synchronize the rotation of module 5 with motion of the sun. The reflectors and receivers (e.g., module) may be inclined (as shown) to account for the effect of geographic latitude on inclination of the sun at the location where the system is deployed. In the illustrated example, the rotating support, receiver, and Fresnel reflectors may track the sun azimuthally so that the Fresnel reflectors concentrate sun light azimuthally.

In an example of East-West concentration with East-West tracking, one or more reflector/receiver assemblies (e.g., any of those described above) are oriented with their receivers aligned (or approximately aligned) in a North-South direction. The reflector/receiver assemblies so aligned are mounted on or otherwise (e.g., rigidly) connected to a rotation mechanism allowing reflectors and receivers to rotate together around an (or an approximately) North-South axis to track the East-West motion of the sun during the day and hence focus reflected sunlight to a (or an approximately) North-South line or linearly extending spot on the receiver or receivers. Such tracking may, for example, orient the reflector/receiver assemblies so that the sun lies in the plane defined by the receivers and optical axes of their associated reflectors. Any suitable rotation mechanism or combination of rotations mechanisms may be used. Some variations may utilize, for example, one or more wheels, rollers, rotation bearings, axels, or combination thereof. In some variations, the approximately North-South rotation axis is inclined with respect to the horizontal to tilt the one or more reflector/receiver assemblies toward the equator. Such inclination may be at an angle, for example, of approximately the latitude of the location at which the CPV system is installed. In some variations, the rotation axis is located at or near the center of mass of the reflector/receiver assembly or assemblies to be rotated about the axis.

In an example of North-South concentration with North-South tracking, one or more reflector/receiver assemblies (e.g., any of those described above) are oriented with their receivers aligned (or approximately aligned) in an East-West direction. The reflector/receiver assemblies so aligned are mounted on or otherwise (e.g., rigidly) connected to a rotation mechanism allowing reflectors and receivers to rotate together around an (or an approximately) East-West axis to track the North-South (inclination angle) motion of the sun during the day and hence focus reflected sunlight to a (or an approximately) East-West line or linearly extending spot on the receiver or receivers. Such tracking may, for example, orient the reflector/receiver assemblies so that the sun lies in the plane defined by the receivers and optical axes of their associated reflectors. Any suitable rotation mechanism or combination of rotations mechanisms may be used. Some variations may utilize, for example, one or more wheels, rollers, rotation bearings, axels, or combination thereof. In some variations, the rotation axis is located at or near the center of mass of the reflector/receiver assembly or assemblies to be rotated about the axis.

This disclosure is illustrative and not limiting. Further modifications will be apparent to one skilled in the art in light of this disclosure and are intended to fall within the scope of the appended claims.

What is claimed is:

1. A concentrating solar energy collector comprising:
an elongated solar receiver comprising one or more photovoltaic cells; and
an elongated Fresnel reflector having a long axis oriented parallel to a long axis of the receiver and arranged to reflect solar radiation to the photovoltaic cells when the Fresnel reflector and the solar receiver are oriented such that the sun lies in or approximately in a plane defined by an optical axis of the Fresnel reflector and a long axis of the receiver;
wherein the Fresnel reflector comprises a plurality of elongated reflective elements fixed with respect to each other and with respect to the receiver and having long axes oriented parallel to the long axes of the Fresnel reflector and the receiver; and
wherein the long axes of the reflective elements lie on or approximately on a parabola.

2. The concentrating solar energy collector of claim I wherein the reflective elements have widths transverse to their long axes of about 5% to about 10% of a width of the Fresnel reflector transverse to its long axis.

3. The concentrating solar energy collector of claim 1 further comprising a rotation mechanism allowing the receiver and Fresnel reflector to be oriented to track the sun.

4. The concentrating solar energy collector of claim 3, wherein the rotation mechanism allows azimuthal rotation of the receiver and the Fresnel reflector.

5. The concentrating solar energy collector of claim 3, wherein the rotation mechanism allows the receiver and the Fresnel reflector to be rotated about a North-South axis, or about an approximately North-South axis, to track East-West motion of the sun.

6. The concentrating solar energy collector of claim 3, wherein the rotation mechanism allows the receiver and the Fresnel reflector to be rotated about an East-West axis, or about an approximately East-West axis, to track North-South motion of the sun.

7. The concentrating solar energy collector of claim 1, wherein the receiver has a “V”-shape cross-section, or an approximately “V”-shape cross-section, in a plane transverse to its long axis.

8. The concentrating solar energy collector of claim 3, wherein the receiver has a “V”-shape cross-section, or an approximately “V”-shape cross-section, in a plane transverse to its long axis.

9. The concentrating solar energy collector of claim 1, wherein the reflective elements are arranged to stagger their ends, to stagger gaps between adjacent collinear or approximately collinear reflective elements, or both.

10. The concentrating solar energy collector of claim 3, wherein the reflective elements are arranged to stagger their ends, to stagger gaps between adjacent collinear or approximately collinear reflective elements, or both.

11. The concentrating solar energy collector of claim 7, wherein the reflective elements are arranged to stagger their ends, to stagger gaps between adjacent collinear or approximately collinear reflective elements, or both.

12. The concentrating solar energy collector of claim 8, wherein the reflective elements are arranged to stagger their ends, to stagger gaps between adjacent collinear or approximately collinear reflective elements, or both.

13. The concentrating solar energy collector of claim 1, wherein the photovoltaic cells are liquid-cooled.

14. The concentrating solar energy collector of claim 7, wherein the photovoltaic cells are liquid-cooled.

15. A concentrating solar energy collector comprising:
an elongated liquid-cooled solar receiver comprising one or more photovoltaic cells; and
an elongated reflector having a long axis oriented parallel to a long axis of the receiver and arranged to reflect solar radiation to the photovoltaic cells when the reflector and the solar receiver are oriented such that the sun lies in or approximately in a plane defined by an optical axis of the reflector and a long axis of the receiver;
wherein the receiver has a “V”-shaped cross-section, or an approximately “V”-shaped cross-section, in a plane transverse to its long axis.

16. The concentrating solar energy collector of claim 15 further comprising a rotation mechanism allowing the receiver and the reflector to be oriented to track the sun.

17. The concentrating solar energy collector of claim 16, wherein the rotation mechanism allows azimuthal rotation of the receiver and the reflector.

18. The concentrating solar energy collector of claim 16, wherein the rotation mechanism allows the receiver and the reflector to be rotated about a North-South axis, or about an approximately North-South axis, to track East-West motion of the sun.

19. The concentrating solar energy collector of claim 16, wherein the rotation mechanism allows the receiver and the reflector to be rotated about an East-West axis, or about an approximately East-West axis, to track North-South motion of the sun.

20. The concentrating solar energy collector of claim 15, wherein the reflector has a parabolic or approximately parabolic cross-section transverse to its long axis.

21. The concentrating solar energy collector of claim 16, wherein the reflector has a parabolic or approximately parabolic cross-section transverse to its long axis.

22. The concentrating solar energy collector of claim 15, wherein the reflector comprises a plurality of elongated reflective elements fixed with respect to each other and with respect to the receiver and having long axes oriented parallel to the long axes of the reflector and the receiver.

23. The concentrating solar energy collector of claim 16, wherein the reflector comprises a plurality of elongated reflective elements fixed with respect to each other and with respect to the receiver and having long axes oriented parallel to the long axes of the reflector and the receiver.

24. The concentrating solar energy collector of claim 22, wherein the reflective elements are arranged to stagger their ends, to stagger gaps between adjacent collinear or approximately collinear reflective elements, or both.

25. The concentrating solar energy collector of claim 23, wherein the reflective elements are arranged to stagger their ends, to stagger gaps between adjacent collinear or approximately collinear reflective elements, or both.

26. A concentrating solar energy collector comprising:
an elongated solar receiver comprising one or more photovoltaic cells; and
an elongated Fresnel reflector having a long axis oriented parallel to a long axis of the receiver and arranged to reflect solar radiation to the photovoltaic cells when the Fresnel reflector and the solar receiver are oriented such that the sun lies in or approximately in a plane defined by an optical axis of the Fresnel reflector and a long axis of the receiver;
wherein the Fresnel reflector comprises a plurality of elongated reflective elements fixed with respect to each other and with respect to the receiver and having long axes oriented parallel to the long axes of the Fresnel reflector and the receiver; and
wherein the reflective elements are arranged to stagger their ends, to stagger gaps between adjacent collinear or approximately collinear reflective elements, or both.

27. The solar energy concentrating collector of claim 26, wherein the receiver is liquid-cooled.

28. The concentrating solar energy collector of claim 26 further comprising a rotation mechanism allowing the receiver and Fresnel reflector to be oriented to track the sun.

29. The concentrating solar energy collector of claim 28, wherein the rotation mechanism allows azimuthal rotation of the receiver and the Fresnel reflector.

30. The concentrating solar energy collector of claim 28, wherein the rotation mechanism allows the receiver and the Fresnel reflector to be rotated about a North-South axis, or about an approximately North-South axis, to track East-West motion of the sun.

31. The concentrating solar energy collector of claim 28, wherein the rotation mechanism allows the receiver and the Fresnel reflector to be rotated about an East-West axis, or about an approximately East-West axis, to track North-South motion of the sun.
